(19) United States
(12) Patent Application Publication
(10) Pub. No.: US 2002/0064935 A1
(43) Pub. Date: May 30, 2002

(54) Semiconductor device and manufacturing method the same

(76) Inventor: Hirokazu Honda, Tokyo (JP)

Correspondence Address: Hayes Soloway, 175 Canal Street, Manchester, NH, 03101, US

(21) Appl. No.: 10/052,143

(22) Filed: Jan. 17, 2002

Related U.S. Application Data
(62) Division of application No. 09/712,105, filed on Nov. 14, 2000.

(30) Foreign Application Priority Data
Nov. 16, 1999 (JP) 325770/1999

(51) Int. Cl. H01L 21/4763

(52) U.S. Cl. 438/622; 438/613; 438/106; 438/110

(57) ABSTRACT

A semiconductor device includes pads formed on a semiconductor chip, conductive sections connected to the pads, respectively, conductive bumps on surfaces of the conductive sections, and an insulating film covering the semiconductor chip other than the surfaces of the conductive sections. The insulating film including a stress buffering layer in a lateral direction of the conductive sections to relax a stress applied to the bumps.

### BACKGROUND OF THE INVENTION

1. Field of the Invention

The present invention relates to a semiconductor device and a manufacturing method the same, and more particularly to a semiconductor device having the structure for avoiding damages on metal bumps, which are caused by a thermal expansion coefficient, and a manufacturing method thereof.

2. Description of the Related Art

In recent semiconductor devices, new form of packages have been developed to comply with demands for electronic devices having high performance, small size, light weight, and high speed. Smaller and slimmer devices have been realized by high integration of semiconductor chips to be mounted, and much higher performance and speed are aimed at electronic devices. A package according to FCBGA (Flip Chip Ball Grid Array) method has appeared.

FIGS. 1A to 1D are side views showing a semiconductor device according to the FCBGA method. FIG. 1A shows a semiconductor chip 31, and FIG. 1B shows an installed state of the semiconductor chip 31 on a printed circuit board 32. The semiconductor chip 31 has a plurality of electrode pads arranged in a predetermined array at a peripheral portion or active region. Metal bumps 25 are respectively provided on the electrode pads. The semiconductor chip 31 is installed, by an end user, on the multi-layer printed circuit board (equipment board) 32 having electrodes arranged in the same pattern as that of the array pattern of the bumps.

In general, if the metal bumps are made of solder balls, the solder balls are subjected to reflow at a predetermined temperature. Thus, the semiconductor chip 31 is mounted on the multi-layer printed circuit board 32. At this time, stress distortion is caused due to a difference in thermal expansion coefficient between the semiconductor chip 31 and the multi-layer printed circuit board 32, resulting in a problem that the installation reliability is deteriorated. To solve this problem, the following countermeasure has been taken.

For example, expensive ceramics-based material such as aluminum nitride (AlN), mullite, or glass-ceramics is used for the multi-layer printed circuit board 32. Thus, the linear expansion coefficient of the multi-layer printed circuit board 32 is made closer to that of silicon which is a main material of the semiconductor chip 31, so that the mismatching between the linear expansion coefficients is minimized to improve the installation reliability. This countermeasure is effective from the viewpoint of improvements of the installation reliability. However, the material of the multi-layer printed circuit board 32 is so expensive that its application is limited to expensive devices such as super computers and large-scale computers.

Hence, the technique has been developed in which there is used a multi-layer printed circuit board formed of organic-based material of a relatively low price and a large linear expansion coefficient. In this case, an under-fill resin layer is inserted between the multi-layer printed circuit board and a semiconductor chip, so that shearing stress which acts on bump connecting sections is distributed to reduce stress distortion. Thus, the installation reliability is improved.

In this technique, a multi-layer printed circuit board of a low price can be used. However, an interface peeling phenomenon is induced in the reflow process if there are voids in the under-fill resin layer or if the interface between the under-fill resin layer and the semiconductor chip or between the under-fill resin layer and the multi-layer printed circuit board provides poor adhesion. As a result, it is easily caused that products are degraded.

A package according to the FCBGA method is generally used for a large-scale semiconductor integrated circuit (LSI) having high performance, and the product itself is expensive. Therefore, if an error is detected in other parts than the semiconductor chip through an electrical selection process after actual installation of the semiconductor chip, the semiconductor chip is detached from the multi-layer printed circuit board and is used again. In the process of the detachment, as shown in FIG. 1C, the non-defective semiconductor chip 31 is heated and suctioned and pulled up by a suction heat tool 33, while the bump connecting sections is melt. Thus, the non-defective semiconductor chip 31 is detached from the multi-layer printed circuit board 32.

Normally, when the semiconductor chip 31 is detached, the metal bumps are damaged while the chip body is not damaged, as shown in FIG. 1D. However, in case of a semiconductor device in which the under-fill resin layer is inserted between the semiconductor chip 31 and the multi-layer printed circuit board 32, damages are not limited to the metal bumps 25 but are effected on the peripheral devices including the multi-layer printed circuit board 32 and a passivation film which protects active regions of the semiconductor chip. In this case, a recovery process for the semiconductor chip 31 is almost impossible. It cannot be considered that use of a multi-layer printed circuit board of a low cost which is made of organic material always promotes cost-down.

In conjunction with the above description, a ship size package is disclosed in Japanese Laid Open Patent Application (JP-A-Heisei 9-64236). In this reference, a chip 10 is connected to a laminate circuit board 20 via direct through-holes 30 in a flip-chip manner. The laminate circuit board 20 has the same size as the chip 10. A gap between the laminate circuit board 20 and the chip 10 is filled with under-fill (40). The chip 10 is connected to external terminals 50 via wiring lines 21 to 24 and via-holes 31. The whole chip 10 including the board 20 is covered other than openings 61 by encapsulant.

Also, a semiconductor device is disclosed in Japanese Laid Open Patent Application (JP-A-Heisei 10-135270). In this reference, a semiconductor chip 21 has a structure a first connection electrode 23 is formed in a peripheral portion of a silicon substrate 22 and is exposed through an opening 25 of a protection film 24. An insulating film 30 is formed on the whole surface of the semiconductor chip 21 other than the opening 25. A wiring line 37 as an electroless plating layer is formed on the first connection electrode 23 and in a ditch 32 formed in the insulating film 30. A second connection electrode 36 as an electroless plating layer is formed in a ditch 33. The ditch 33 is formed in the insulating film 30 on the lower side of the semiconductor ship 22. A protection film 38 is formed on the wiring line 37. A solder bump 39 is formed on the second connection electrode 36. Thus, any interposer or a sub-circuit board is not used in a semiconductor device of a CSP type.

Also, a flip chip IC is disclosed in Japanese Laid Open Patent Application (JP-A-Heisei 10-163266). In this reference, a bump 112 is connected with an electrode 4 formed on a semiconductor substrate 14 through a metal film 18. The surface of the semiconductor substrate 14 is covered by a second protection film 20 made of polyimide. An opening 8 is formed in the second protection film 20 on a position between the electrode 4 and the bump 112 to expose at least a part of the surface of the metal film 18. Therefore, after the bump 112 is formed, it is possible to test the electric characteristic of the flip chip IC by connecting a probe 114 to the surface of the metal film 18 through the opening 8 without connecting to the bump 112.

Also, a test connector is disclosed in Japanese Patent No. 2,658,831. In this reference, the test connector is produced through an electrode section opening process, an electrode embedding process and an electrode finishing process. A test semiconductor device to be tested has bumps on its surface. The bumps are connected by a flip chip method in which wiring lines are not used. The test connector has a sheet-like shape and electrodes supported by a supporting substrate are connected to the bumps for an electric test. In the electrode opening process, openings for electrode sections are formed in a sheet using a punch and a die. In the electrode section embedding process, electrodes are inserted in the openings and then heat-resistant insulating material is injected and hardened as an insulting film. In the electrode section fining process, the sheet is removed. Thus, ends of each of the electrodes protrude from the insulating film.

### SUMMARY OF THE INVENTION

Therefore, an object of the present invention is to provide a semiconductor device, in which an under-fill resin layer is not required between a semiconductor chip and a multi-layer printed circuit board, and a manufacturing method the same.

Another object of the present invention is to provide a semiconductor device, in which deformation stress acting on metal bumps can be relaxed to improve the installation reliability, and a manufacturing method the same.

Still another object of the present invention is to provide a semiconductor device, in which damages during recovery process for peripheral devices including an installation board can be avoided to realize low costs.

In order to achieve an aspect of the present invention, a semiconductor device includes pads formed on a semiconductor chip, conductive sections connected to the pads, respectively, conductive bumps on surfaces of the conductive sections, and an insulating film covering the semiconductor chip other than the surfaces of the conductive sections. The insulating film including a stress buffering layer in a lateral direction of the conductive sections to relax a stress applied to the bumps.

Here, the insulating film may cover the semiconductor chip other than the surfaces of the conductive sections without including a printed circuit board.

Also, the stress buffering layer may have an elastic modulus in a range of 0.01 to 8 Gpa. Also, it is desirable that the stress buffering layer is formed of material including at least one selected from a group consisting of epoxy-based resin, silicon-based resin, polyimide-based resin, polyolefin-based resin, cyanate-ester-based resin, phenol-based resin, naphthalene-based resin, and fluorine-based resin. When the stress buffering layer includes a plurality of buffering layers, each of the plurality of buffering layers may be formed of material including at least one selected from a group consisting of epoxy-based resin, silicon-based resin, polyimide-based resin, polyolefin-based resin, cyanate-ester-based resin, phenol-based resin, naphthalene-based resin, and fluorine-based resin. In this case, each of the conductive sections may include a plurality of portions respectively corresponding to the plurality of buffering layers.

Also, the conductive section may be connected to the pad via a wiring pattern provided on the semiconductor chip via a first insulting film of the insulating film. In this case, it is desirable that the wiring pattern is formed of copper (Cu). Also, the wiring pattern may extend to adjust a pitch between the conductive bump and another conductive bump. Further, the first insulating film may include a passivation film covering the semiconductor chip other than the pads, and a second insulating film formed on the passivation film. In this case, it is desirable that the second insulating film has a pyrolysis temperature of 200° C. or more. In addition, the second insulating film may be formed of a photosensitive material.

In another aspect of the present invention, a method of manufacturing a semiconductor device, is attained by (a) providing a semiconductor substrate formed on which pads are formed and on which a first insulating film are formed to have openings, the pads being exposed by the openings; (b) forming wiring patterns to extend on the first insulating film and to be respectively connected to the pads; by (c) forming a stress buffering layer on the wiring patterns and the first insulating film, the buffering layer including conductive sections respectively connected to the wiring patterns and a buffering and insulating layer formed to surround the conductive sections on lateral sides thereof; and by (d) forming conductive bumps on surfaces of the conductive sections. The method may further include (e) separating the semiconductor substrate into semiconductor chips.

Here, the (a) providing may be attained by forming the pads; by forming a passivation film on the semiconductor substrate to have openings in the pads; and by forming a second insulating film formed on the passivation film. In this case, the second insulating film may be formed of material having a pyrolysis temperature of 200° C. or more. Also, the second insulating film may be formed of a photosensitive material.

Also, the (b) forming may be attained by carrying out electrolysis plating to produce a conductive layer; and by patterning the conductive layer to produce the wiring patterns.

Also, the (c) forming may be attained by connecting the conductive sections to the wiring patterns; by forming the buffering and insulating layer to cover the first insulating film and the wiring patterns; and by polishing the buffering and insulating layer and the conductive sections to expose the surfaces of the conductive sections. In this case, it is desirable that the buffering and insulating layer has an elastic modulus in a range of 0.01 to 8 Gpa. Also, the buffering and insulating layer is desirably formed of material including at least one selected from a group consisting of epoxy-based resin, silicon-based resin, polyimide-based resin, polyolefin-based resin, cyanate-ester-based resin, phenol-based resin, naphthalene-based resin, and fluorine-based resin.

Instead, when the buffering and insulating film includes first and second buffering and insulating films, and each of the conductive sections includes first and second conductive sections, the (c) forming may be attained by connecting the first conductive sections to the wiring patterns; by forming the first buffering and insulating layer to cover the first insulating film and the wiring patterns; by polishing the first buffering and insulating layer and the first conductive sections to expose the surfaces of the first conductive sections; by connecting the second conductive sections to the first conductive sections; by forming the second buffering and insulating layer to cover the first buffering and insulating layer and the second conductive sections; and by polishing the second buffering and insulating layer and the second conductive sections to expose the surfaces of the second conductive sections. In this case, it is desirable that each of the first and second buffering and insulating layers has an elastic modulus in a range of 0.01 to 8 Gpa. Also, each of the first and second buffering and insulating layers is desirably formed of material including at least one selected from a group consisting of epoxy-based resin, silicon-based resin, polyimide-based resin, polyolefin-based resin, cyanate-ester-based resin, phenol-based resin, naphthalene-based resin, and fluorine-based resin.

### BRIEF DESCRIPTION OF THE DRAWINGS

FIG. 1A shows a conventional semiconductor chip;

FIG. 1B shows an installed state of the conventional semiconductor chip on a printed circuit board;

FIG. 1C shows a process of the detachment of the conventional semiconductor chip from the printed circuit board;

FIG. 1D shows the metal bumps damaged when the conventional semiconductor chip is detached;

FIGS. 2A to 2S are cross sectional views showing a method of manufacturing a semiconductor device according to a first embodiment of the present invention;

FIGS. 3A to 3F are cross sectional views showing a method of manufacturing a semiconductor device according to a second embodiment of the present invention; and

FIGS. 4A to 4F are cross sectional views showing a method of manufacturing a semiconductor device according to a third embodiment of the present invention.

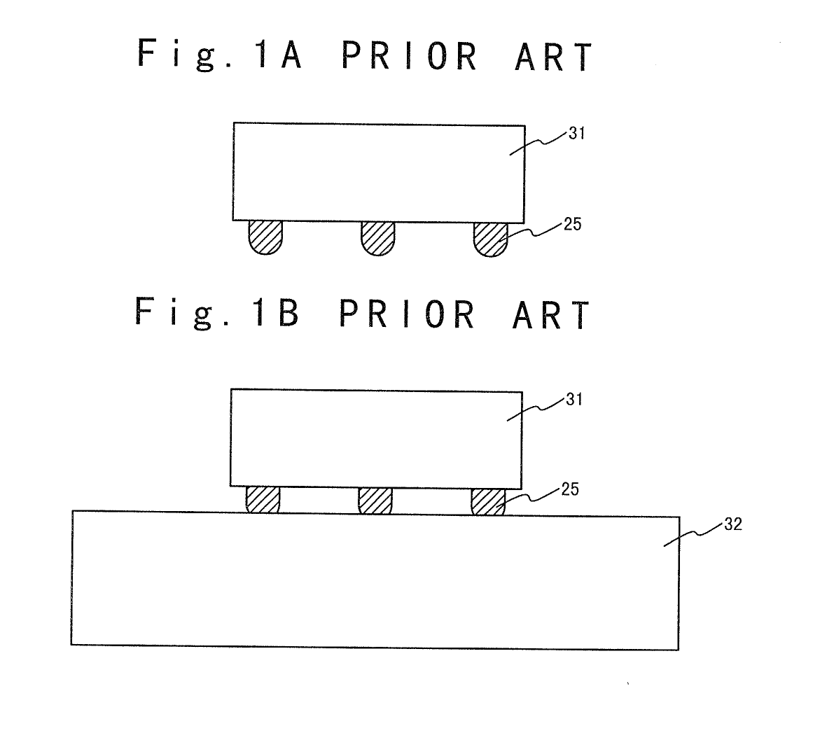

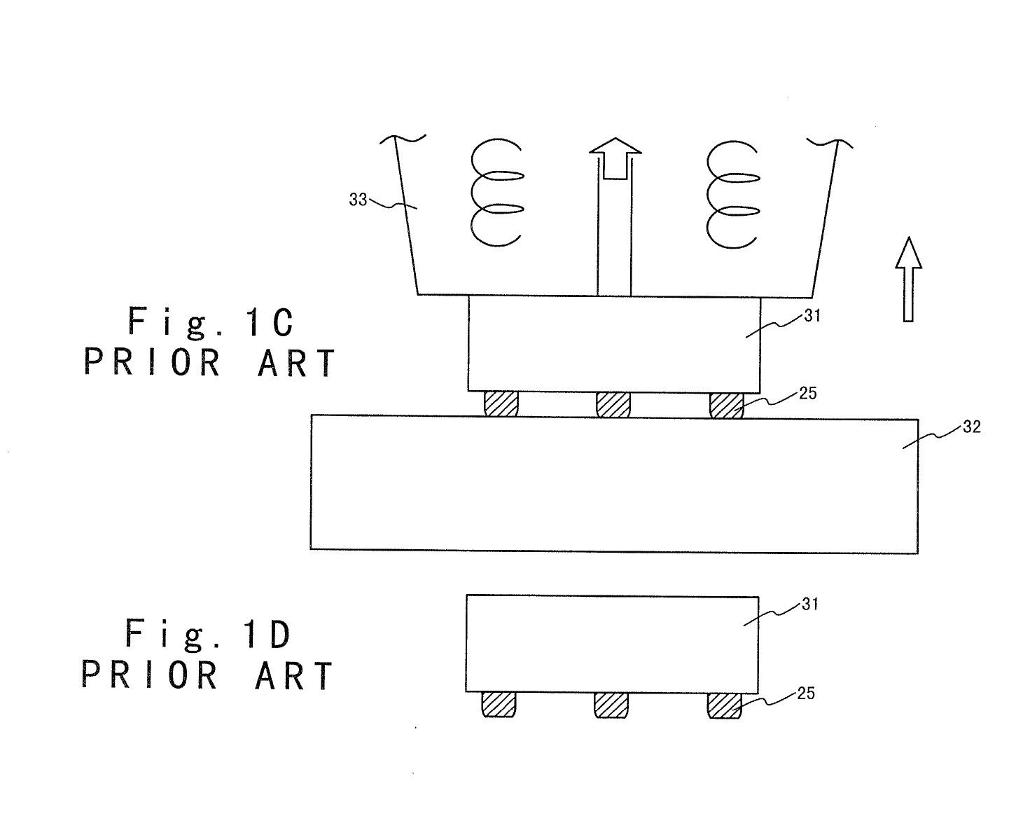

### DESCRIPTION OF THE PREFERRED EMBODIMENTS

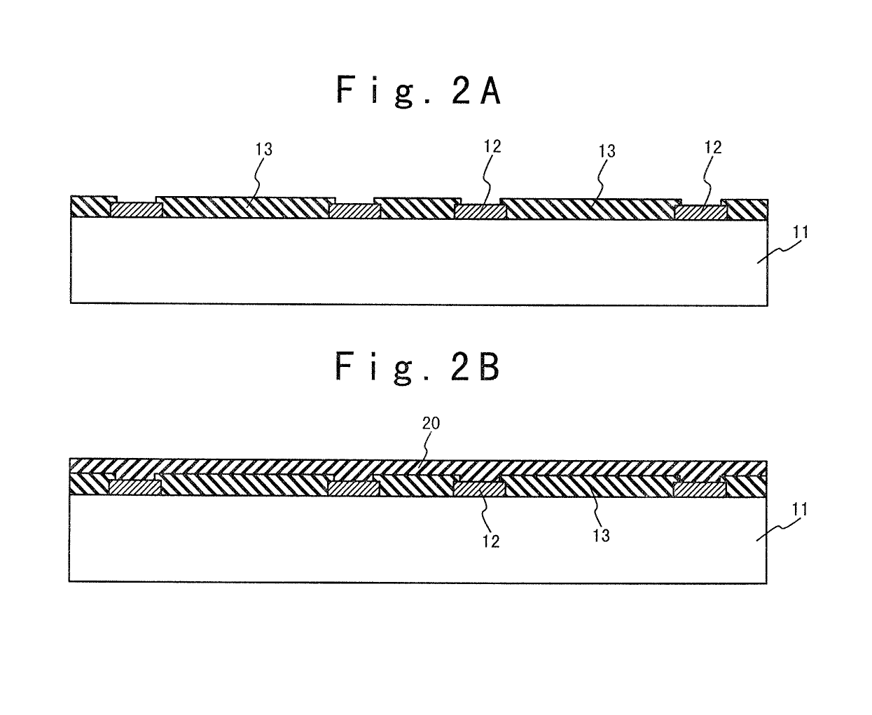

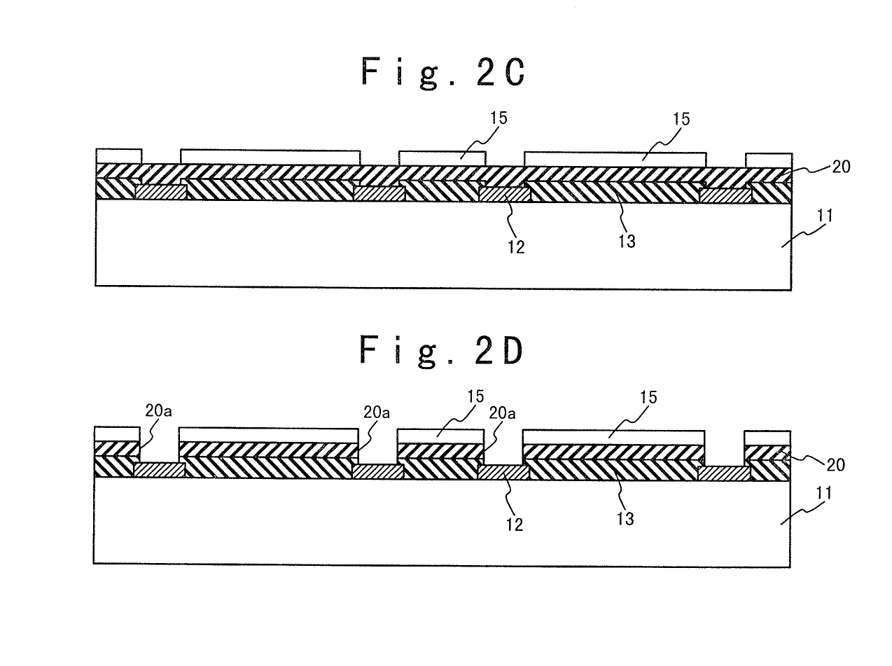

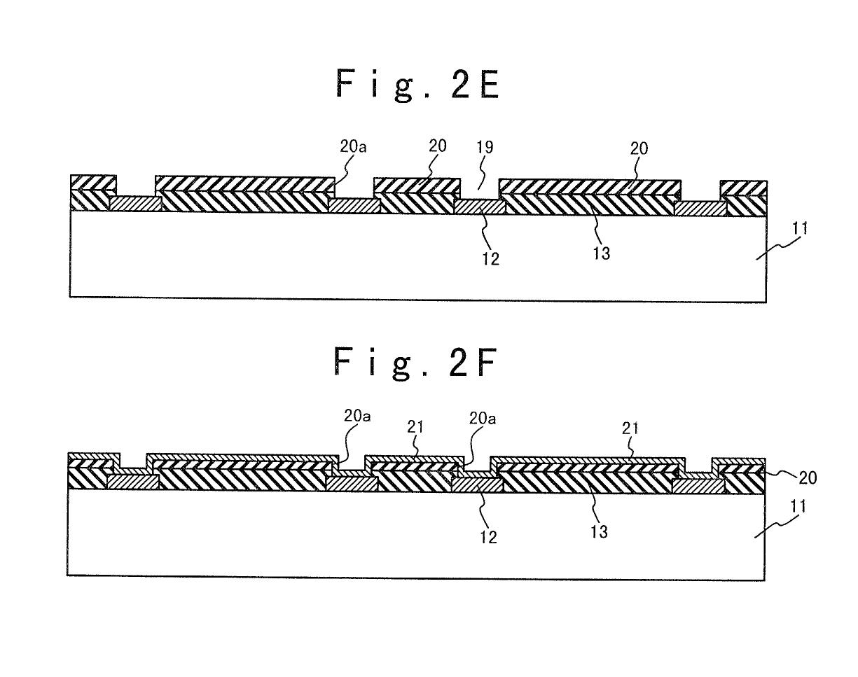

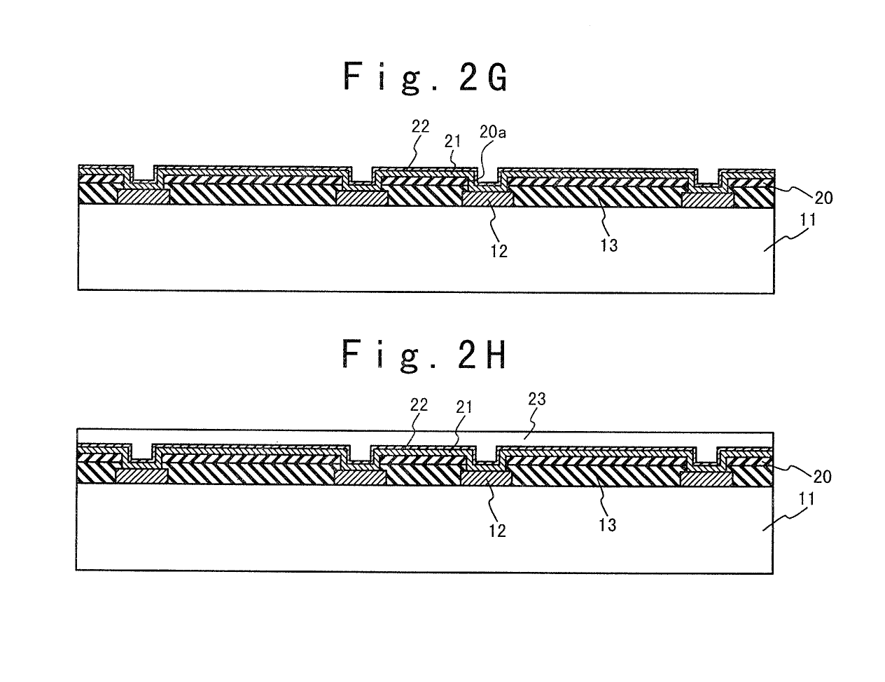

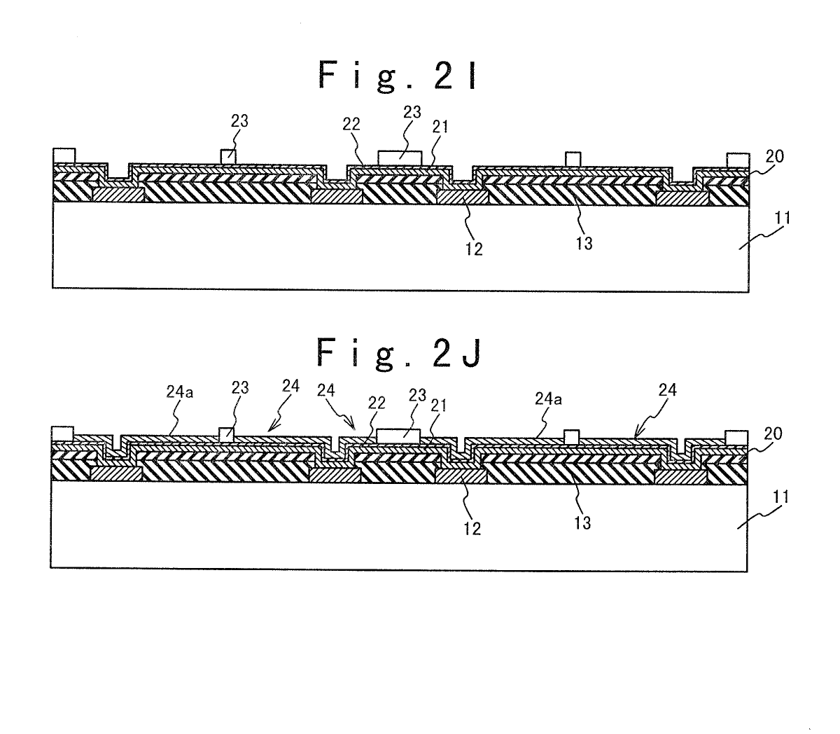

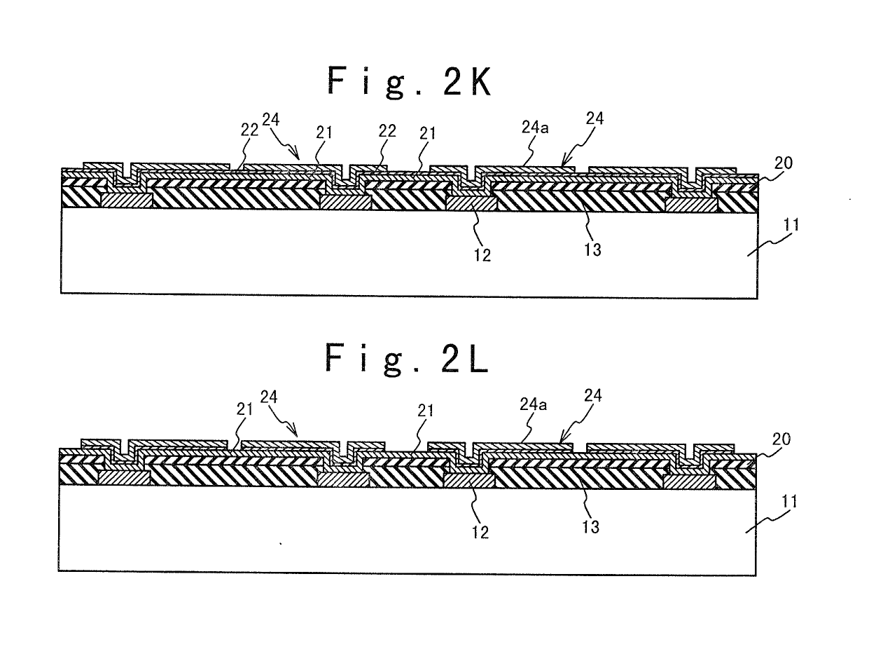

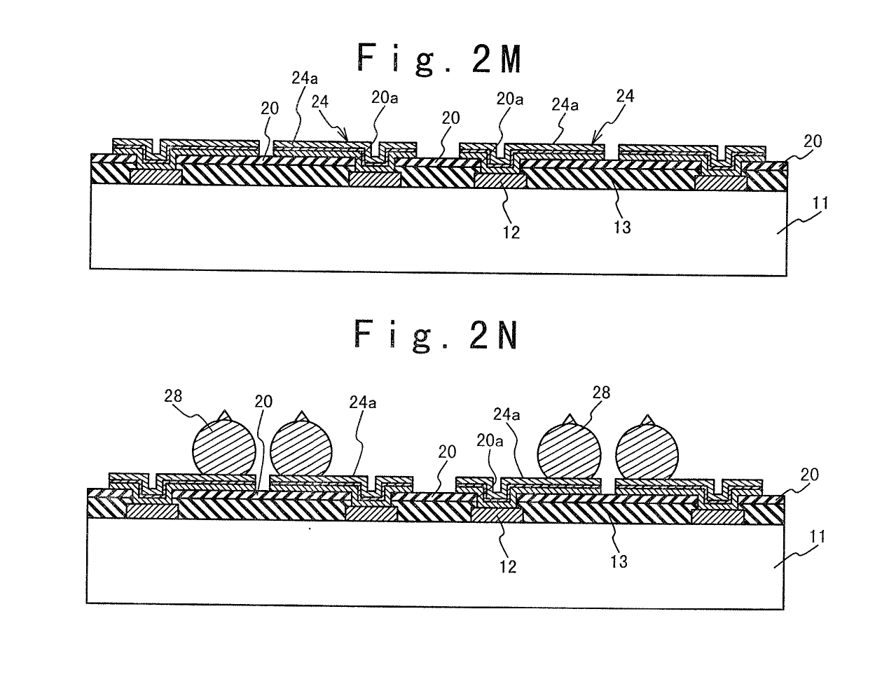

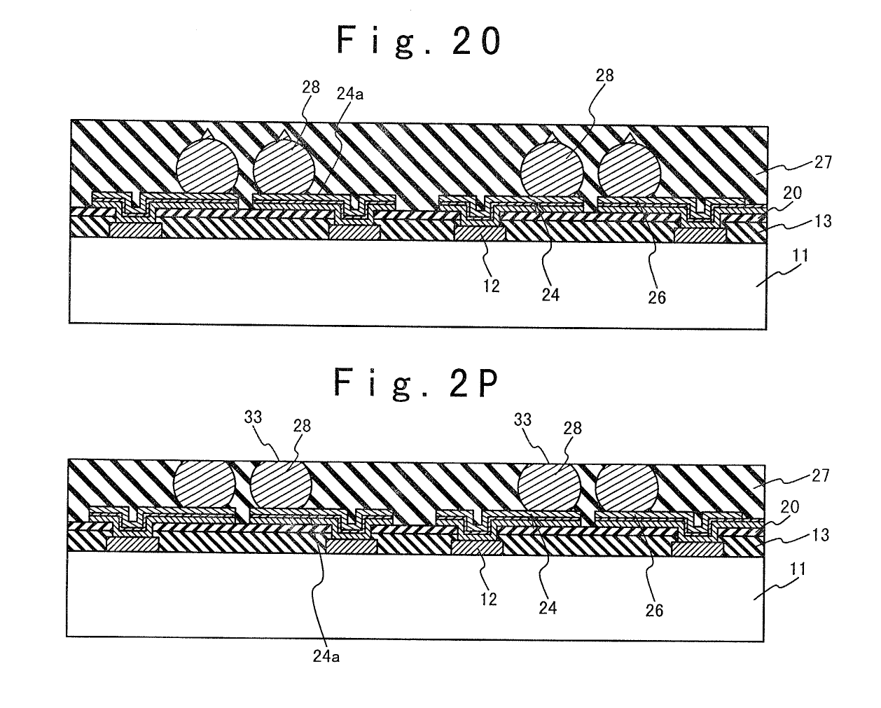

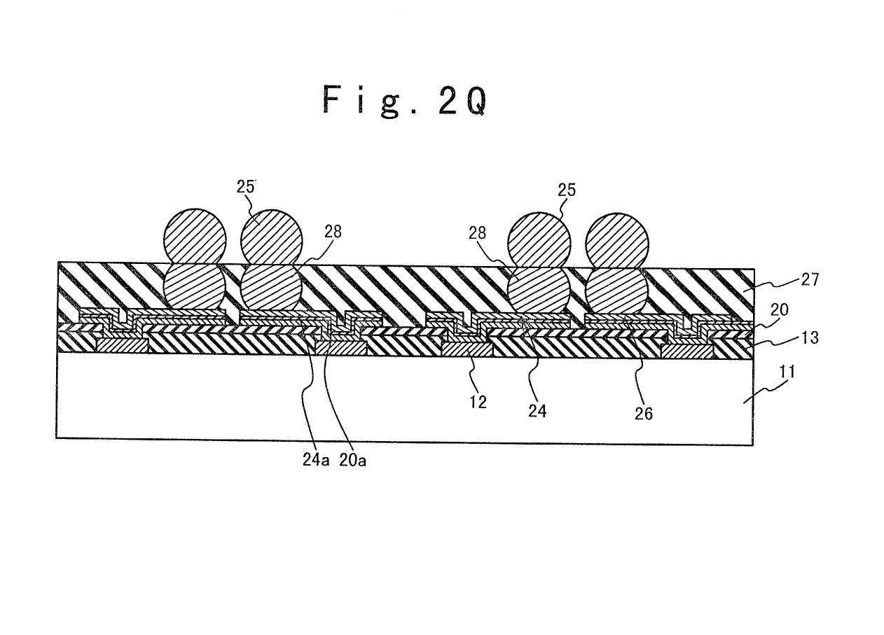

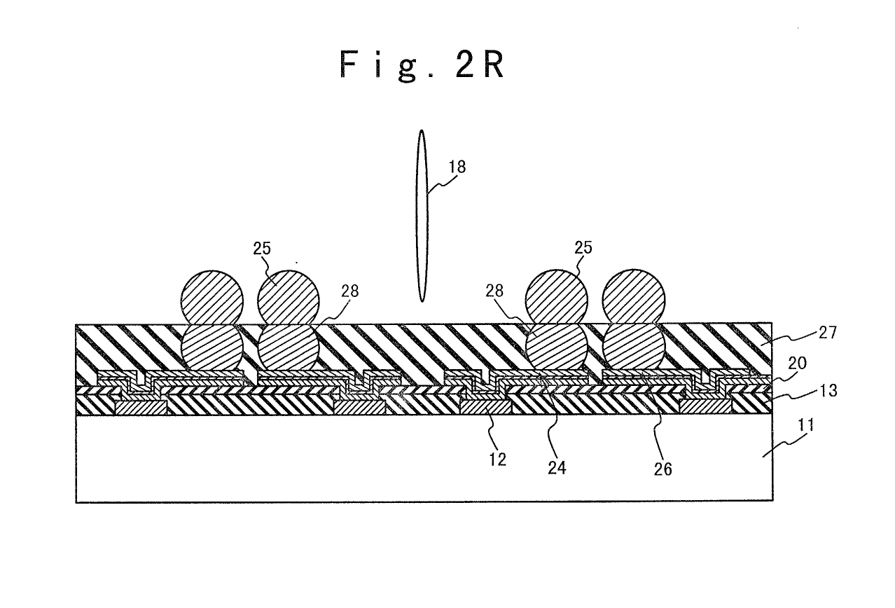

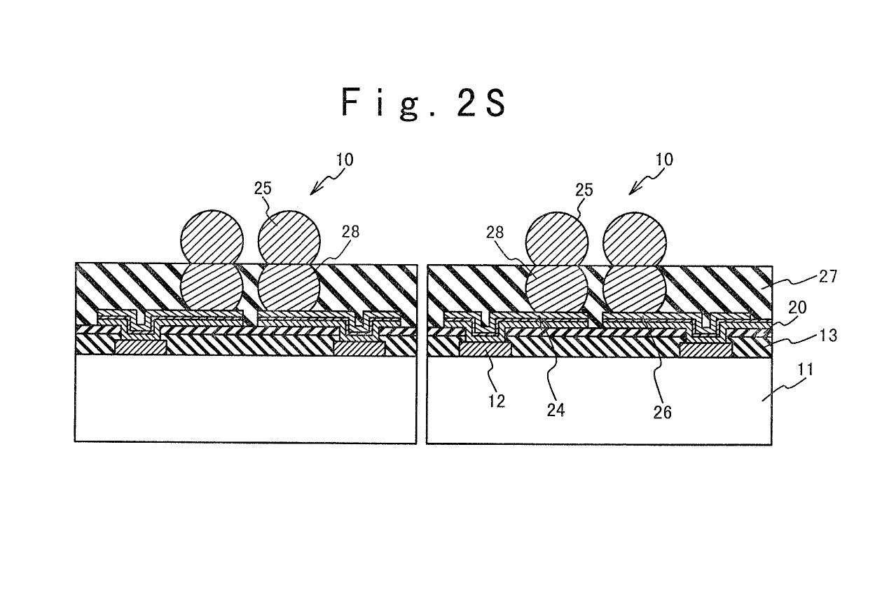

Hereinafter, a semiconductor device of the present invention will now be described in more details with reference to the attached drawings. FIGS. 2A to 2S are cross-sectional views showing a method of manufacturing the semiconductor device of the FCBGA type according to the first embodiment of the present invention.

At first, as shown in FIG. 2A, pad electrodes 12 made of material such as aluminum (Al) or copper (Cu) are formed. The pad electrodes are positioned to be in a peripheral portion of every semiconductor chip. Then, a passivation film 13 is formed on the portions around the pad electrodes 12 and the surfaces of the active regions to mainly protect active regions.

Next, as sown in FIG. 2B, an insulative resin film (insulating layer) 20 is formed on the pad electrodes 12 and the passivation film 13. The insulating resin film 20 is made of inorganic material such as SiO₂ or organic material such as polyimide (PI). Resin material having a pyrolysis temperature of 200° C. or more is used for the insulating resin film 20. When material of a thermal hardening component is mixed in the insulating resin film 20, heat treatment is carried out at a predetermined temperature thereby to promote bridging reaction of resin components. Thus, predetermined physical and chemical properties are attained.

Next, as shown in FIG. 2C, a photoresist layer 15 is formed on the insulating resin film 20. Then, the photoresist layer 15 is subjected to a patterning process by use of a photolithography technique so that the other regions than the regions corresponding to the pad electrodes 12 remain. Subsequently, as shown in FIG. 2D, opening sections 20a are formed in the insulating resin film 20 above the pad electrodes 12, using the patterned photoresist layer 15 as a mask.

Next, as shown in FIG. 2E, the photoresist layer 15 is removed to expose the insulating resin film 20. If the insulating resin film 20 is made of photosensitive material, exposure and development processes can be carried out directly to the insulating resin film 20 for a patterning process. In this case, therefore, the process of forming and removing the photoresist layer 15 is not necessary.

Next, as shown in FIG. 2F, an electrode pad bonding metal layer 21 is formed by a sputtering method as a lower metal thin film. The electrode pad bonding metal layer 21 is formed on the electrode pads 12, inner walls of the opening sections 20a, and the insulating resin film 20, or the like. The electrode pad bonding metal layer 21 is made of metal material such as titanium-based (Ti-based) alloy or chrome (Cr). The bonding metal layer 21 has an excellent adherence characteristic with the electrode pads 12 made of Al or Cu and a soft mutual metal diffusion characteristic. Also, the bonding metal layer 21 has an excellent adherence characteristic with the insulating resin film 20. Prior to formation of the electrode pad bonding metal layer 21, the surfaces of the electrode pads 12 may be subjected to plasma surface treatment to maintain cleanliness of the surfaces of the electrode pads 12 and to improve the activity. In this case, the adherence between the electrode pads 12 and the electrode pad bonding metal layer 21 can be improved much more.

Next, as shown in FIG. 2G, an electroplating electrode metal layer 22 made of metal material such as Cu is formed on the electrode pad bonding metal layer 21 by a sputtering method. The electroplating electrode metal film 22 has a low resistance characteristic and functions as an electroplating electrode after rewiring formation.

Next, as shown in FIG. 2H, a photoresist layer 23 is coated on the electroplating electrode metal layer 22 to form a rewiring layer by an electrolytic plating process. Thereafter, as shown in FIG. 2I, a photoresist layer 23 is subjected to a patterning process by a photolithography technique, to expose only the electroplating electrode metal layer 22 corresponding to a predetermined rewiring pattern. Subsequently, as shown in FIG. 2J, a Cu plated layer 24 is formed only on the electroplating electrode metal layer 22 by an electrolytic Cu plating process.

Next, as shown in FIG. 2K, the photoresist layer 23 is removed to expose the electroplating electrode metal layer 22 which has been covered with the photoresist layer 23. Thereafter, as shown in FIG. 2L, the electroplating electrode metal layer 22 is removed using the Cu plated layer as a mask. Thus, an electroplating electrode metal film 22 is formed.

Next, as shown in FIG. 2M, the electrode pad bonding metal layer 21 is removed by a wet etching method using the Cu plated layer 24 as a mask. Thus, rewiring pattern portions (first conductive portions) 24a are obtained to be insulated from each other and each of the rewiring pattern portions 24a has one end connected to an electrode pad 12 and another end extending from an opening portion 20a onto the insulating resin film 20.

Next, as shown in FIG. 2N, a conductive bump (second conductive portion) 28 is formed on each of the rewiring pattern portions 24a by a wire bonding method using a metal wire containing material such as Cu and solder as a main component. In this case, prior to attachment of the conductive bumps 28, the rewiring pattern portions 24a may be subjected to a cleaning process based on a plasma surface process technique, to improve the mounting characteristic of the conductive bumps 28.

Next, as shown in FIG. 20, an insulating stress buffering resin layer (insulating resin layer) 27 is formed on the entire surface of the semiconductor wafer, to cover the conductive bumps 28 and the rewiring pattern portions 24a. The insulating stress buffering resin layer 27 serves to protect the conductive bumps 28 and the rewiring pattern portions 24a from mechanical and chemical stress. The insulating stress buffering resin layer 27 contains, as its main component, epoxy-based resins, silicon-based resins, polyimide-based resins, polyolefin-based resins, cyanate-ester-based resins, phenol-based resins, naphthalene-based resins, or fluorine-based resins. The insulating stress buffering resin layer 27 preferably has an elastic modulus in a range of 0.01 to 8 GPa (giga-pascal). If the stress buffering resin is liquid when forming the layer, the insulating stress buffering resin layer 27 is formed by a spin-coating method. Otherwise, if the resin is of filmlike material, the insulating stress buffering resin layer 27 can be arranged by a film laminate method. In the film laminate method, a film-like insulating stress buffering resin layer 27 in which opening sections respectively corresponding to the conductive bumps 28 are previously formed is adhered to the insulating resin film 20 such that the opening sections are aligned with the corresponding conductive bumps 28.

Next, as shown in FIG. 2P, an upper portion of the insulating stress buffering resin layer 27 and upper portions of the conductive bumps 29 are polished by a polishing technique such as a plasma surface process technique, and a chemical mechanical polishing technique (CMP). As a result, the upper surfaces of the conductive bumps 28 are exposed from the insulating stress buffering resin layer 27. Also, metal bump formation land portions 33 are formed on the same plane as the surface of the insulating stress buffering resin layer 27.

Next, as shown in FIG. 2Q, metal bumps 25 containing tin (Sn) and lead (Pb) as main components are mounted on the metal bump formation land parts 33. Prior to the mounting of the metal bumps 25, the metal bump formation land parts 33 may be subjected to an electroless Cu plating process, or may further be subjected to an electroless gold (Au) plating process after the electroless Cu plating process. In this case, the solder wetting characteristic can be improved so that the metal bumps 25 can be fixed excellently. Also, if electroless nickel (Ni) plating process is carried out in place of the electroless Cu plating process, the same advantage can be attained. Further, if polishing dust or organic coating generated by polishing process remain on the metal bump formation land parts 33, a cleaning process may be carried out by using a plasma surface process technique.

Alternatively, the metal bumps 25 may be mounted after coating flux (not shown) on the metal bump formation land parts 33, and a heat reflow process may be carried out. In this case, the metal bumps can be excellently fixed. Also, the metal bumps 25 may be made of Au and tin-silver-based (Sn—Ag-based) alloy in place of solder.

Next, as shown in FIG. 2R, a dicing blade 18 is used to cut the wafer-like semiconductor substrate 11 into individual semiconductor chips 10 as shown in FIG. 2S.

In the present embodiment, each rewiring pattern portion 24a has an end connected to an electrode pad 12 and another end extending from the opening part 20a onto the insulating resin film 20. The conductive bump 28 is provided on the latter end of the rewiring pattern portion 24a. A metal bump 25 is provided on the upper surface of each of the conductive bumps 25, which are kept embedded in the insulating stress buffering resin layer 27. Therefore, even if the linear expansion coefficients of the semiconductor chip 10 and the multi-layer printed circuit board 32 are mismatched with each other where the semiconductor chip 10 is actually mounted on the multi-layer printed circuit board 32, the deformation stress which acts on the metal bumps 25 can be effectively absorbed or relaxed by the conductive bumps 25 and the insulating stress buffering resin layer 27. As a result, the installation reliability can be improved. In addition, if only the pattern of the rewiring pattern portion 24a is changed appropriately, the pitch of the metal bumps 25 32 can be changed with respect to each electrode of the multi-layer printed circuit board.

Also, in the present embodiment, an insulating stress buffering resin layer 27 is formed on the entire surface of the wafer-like semiconductor substrate 11, and the steps of manufacturing semiconductor chips 10 can be carried out in units of wafers. Therefore, a large number of semiconductor chips 10 can be separated and obtained from one wafer in the final stage. In this way, the number of processing steps can be reduced greatly so that the manufacturing costs can also be reduced, compared with a packaging method in which separated semiconductor chips are manufactured individually.

Further, since an insulating resin film 20 is formed on the passivation film 13 of the semiconductor chip 10, the passivation film 13 and active regions thereunder can be protected more reliably from heat and mechanical stress generated during a recovery process. As a result of this, it is possible to obtain a package according to the FCBGA method through very easy recovery process.

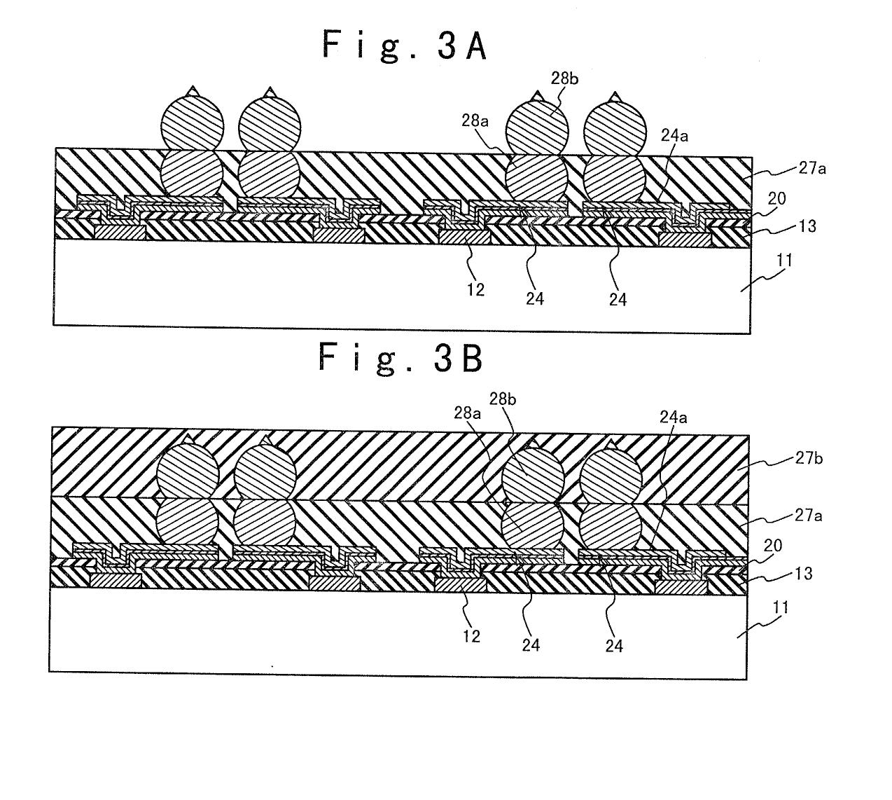

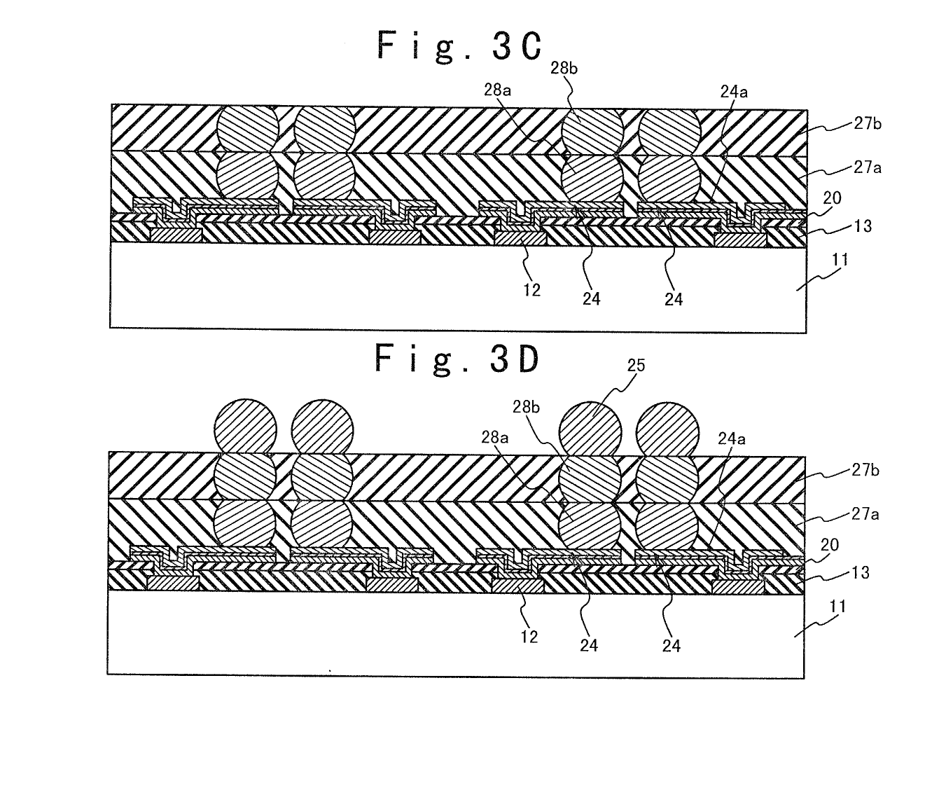

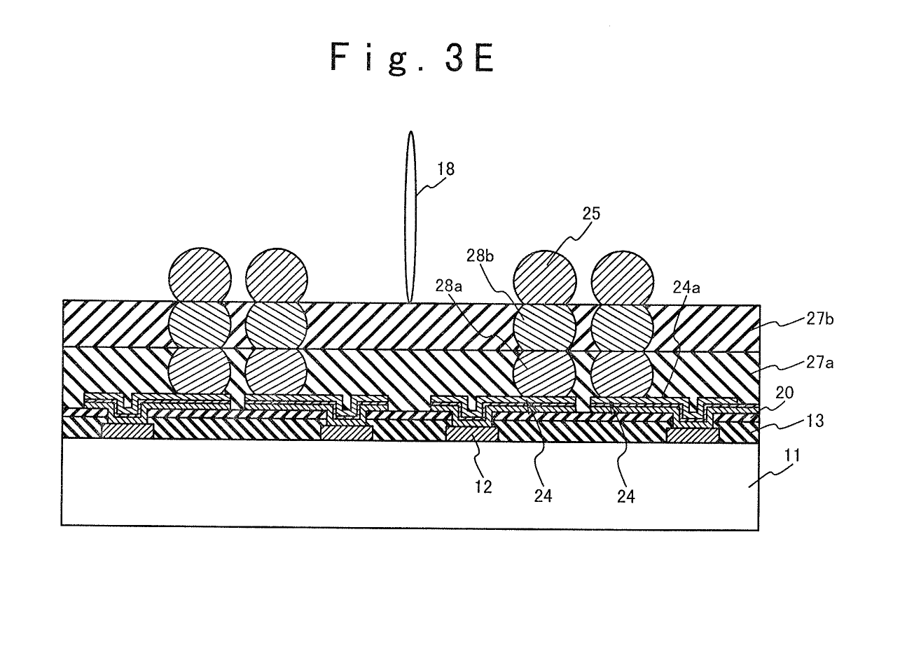

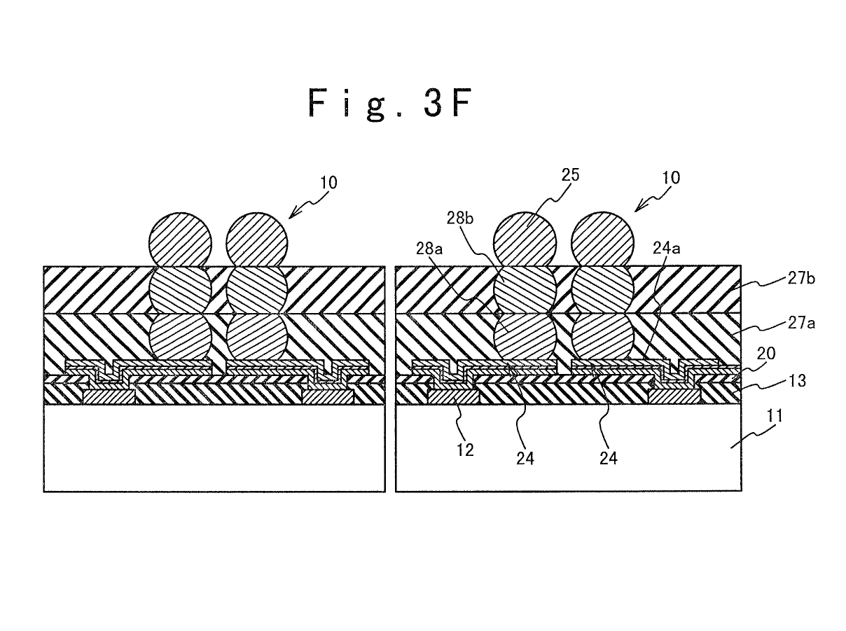

Next, the method of manufacturing a semiconductor device according to the second embodiment of the present invention will be described below. In this embodiment, the process up to FIG. 2P is the same as that of the first embodiment. FIGS. 3A to 3F show steps of manufacturing a semiconductor device according to the second embodiment, following the step shown in FIG. 2P.

As shown in FIG. 3A, portions of the previously formed conductive bumps (hereinafter to be referred to as first conductive bumps) 28 are exposed from the insulating stress buffering resin layer (hereinafter to be referred to as a first insulating stress buffering resin layer) 27a. Second conductive bumps 28b are formed on the exposed portions by a wire bonding method using a metal wire containing material such as Cu and solder as its main component.

As shown in FIG. 3B, a second insulating stress buffering resin layer 27b is formed on the first insulating stress buffering resin layer 27a, to protect the second conductive bumps 28b on the first conductive bumps 28a from mechanical and chemical stress. Like the case of the first insulating stress buffering resin layer 27a, the second insulating stress buffering resin layer 27b is also formed by a spin coating method, film laminate method, press method, or the like.

Further, as shown in FIG. 3C, the upper surface of the second insulating stress buffering resin layer 27b and the second conductive bumps 28b are polished by a plasma surface process technique or a CMP technique, like the case of the first insulating stress buffering resin layer 27a. Thus, the upper surfaces of the second conductive bumps 28b are exposed. Thus, metal bump formation land portions 33 are formed to be positioned on the same plane as the surface of the second insulating stress buffering resin layer 27b.

Next, as shown in FIG. 3D, metal bumps 25 are mounted on the metal bump formation land portions 33 of the second conductive bumps 28b. Further, as shown in FIG. 3E, a dicing blade 18 is used to cut and separate the wafer-like semiconductor substrate 11 into individual semiconductor chips 10, as shown in FIG. 3F.

According to the present embodiment, it is possible to attain the same effects as those of the first embodiment. Compared with the semiconductor device according to the first embodiment, the stand-off upon installation on the multi-layer printed circuit board 32 is higher, and therefore, the deformation stress which acts on the metal bumps 25 can be absorbed more effectively by the first and second conductive bumps 28a and 28b and by the elastic first and second insulating stress buffering resin layers 27a and 27b. Thus, the installation reliability can be improved much more.

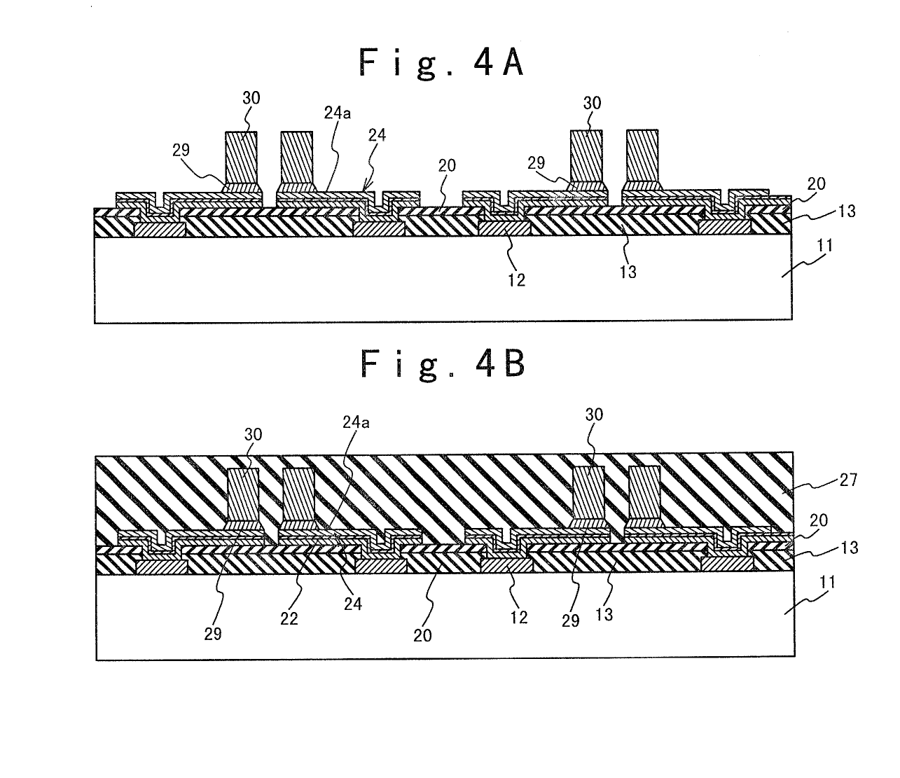

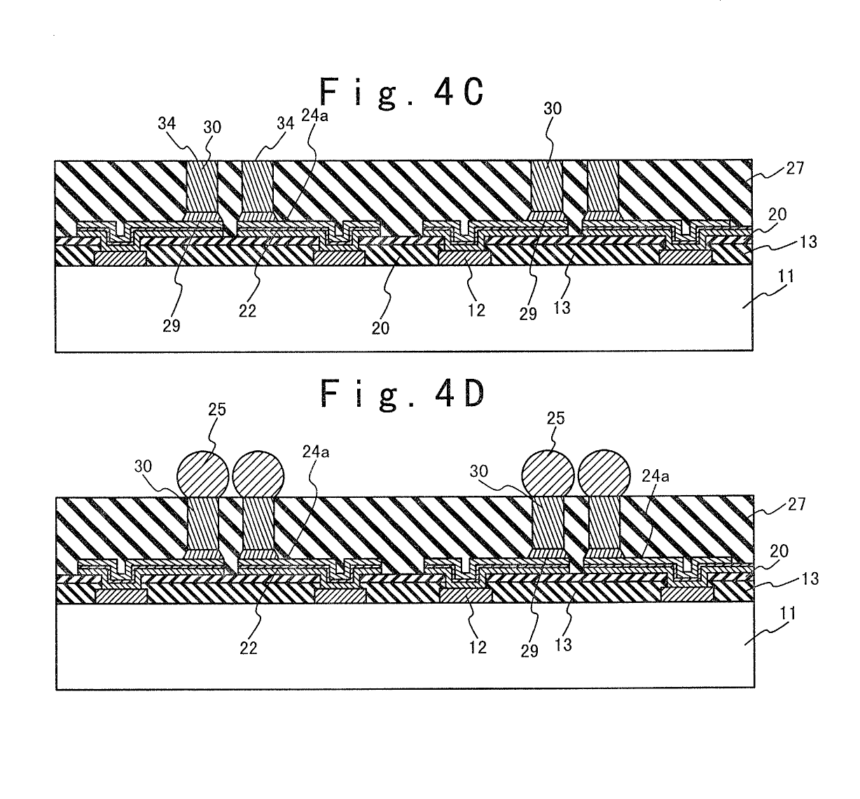

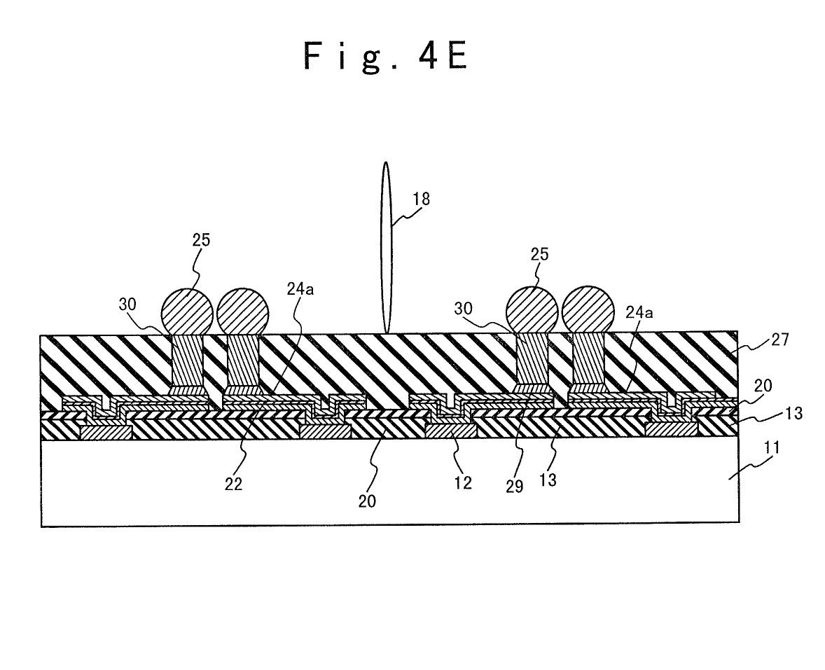

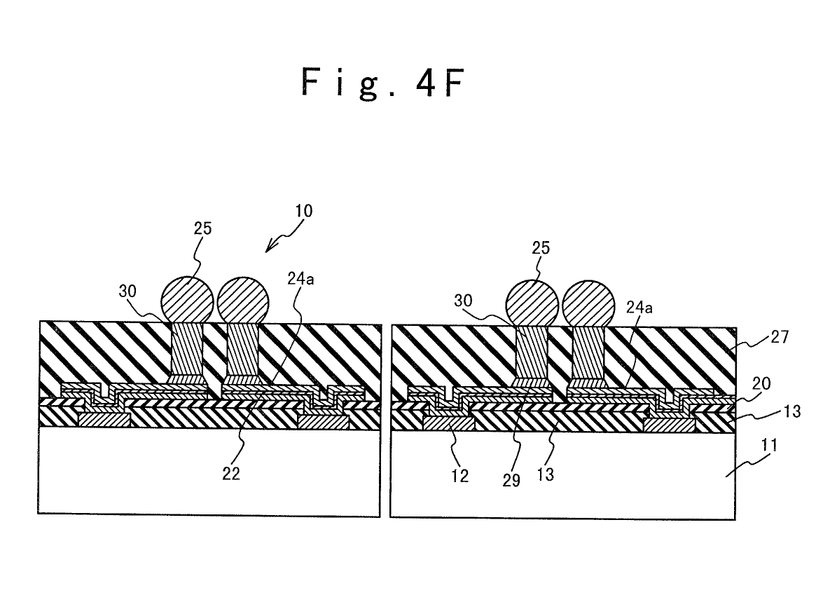

Next, the method of manufacturing a semiconductor device according to the third embodiment of the present invention will be described below. In the present embodiment, the process up to FIG. 2M is the same as that of the previous embodiments. FIGS. 4A to 4F show steps of manufacturing a semiconductor device according to the fourth embodiment, following the step shown in FIG. 2M.

At first, as shown in FIG. 4A, a lower end of each of metal-made circular columnar members 30 is fixed to external terminal forming land portions 24a in the Cu plated layer 24. In this case, the surfaces of the external terminal forming land portions 24a may be subjected to a cleaning process by a plasma surface process technique, prior to fixture of the metal-made circular columnar members 30. Thus, the adherence between the rewiring pattern portions 24a and the metal-made circular columnar members 30 is improved much more.

Conductive adhesions 29 are obtained by mixing at least one of metal powder materials Cu, Pb, Sn, Ni, palladium (Pd), Ag, Au and Al into adhesive resins which contains, as its main component, epoxy-based resins, silicon-based resins, polyimide-based resins, polyolefin-based resins, cyanate-ester-based resins, phenol-based resins, naphthalene-based resins, or fluorine-based resins.

The metal-made circular columnar members 30 are made to contain metal material such as Cu, Ni, Pb, Sn, Al, Iron (Fe), or indium (In) as main component, and preferably have a height ranging from 10 to 200 μm.

Next, as shown in FIG. 4B, an insulating stress buffering resin layer 27 is formed to cover the circular columnar members 30 and the portions 24a, so that the metal-made circular columnar members 30 and rewiring pattern portions 24a are protected from mechanical and chemical stress.

Next, as shown in FIG. 4C, the upper surface of the insulating stress buffering resin layer 27 and the metal-made circular columnar members 30 are polished by a plasma surface process technique or a CMP technique, to form metal bump formation land portions 34 on the same plane as the surface of the second insulating stress buffering resin layer 27.

Next, as shown in FIG. 4D, metal bumps 25 are mounted on the metal bump formation land portions 34, like the first and second embodiments. Subsequently, as shown in FIG. 4E, a dicing blade 18 is used to cut and separate the wafer-like semiconductor substrate 11 into individual semiconductor chips 10, as shown in FIG. 4F.

According to the present embodiment, it is possible to attain the same effects as those of the first embodiment. In addition, another advantage can be obtained in that the metal-made circular columnar members 30 can be easily fixed to the rewiring pattern portions 24a by conductive adhesions 29.

In the above, the present invention has been described on the basis of its preferred embodiments. The semiconductor device and the manufacturing method thereof according to the present invention are not limited to the structures described in the above embodiments but the scope of the present invention includes those semiconductor devices and manufacturing methods thereof that can be attained by variously modifying and changing the structures of the above embodiments.

As has been described above, in the semiconductor device and manufacturing method thereof according to the present invention, deformation stress which acts on metal bumps are relaxed without necessitating an under-fill resin layer between the semiconductor chip and the installation board. It is therefore possible to improve the installation reliability and to avoid damages on peripheral devices in including the installation board during recovering process, so that a low-cost semiconductor device can be realized.

What is claimed is:

1. A semiconductor device, comprising:
pads formed on a semiconductor chip;
conductive sections connected to said pads, respectively;
conductive bumps on surfaces of said conductive sections; and
an insulating film covering said semiconductor chip other than the surfaces of said conductive sections, and
wherein said insulating film including a stress buffering layer in a lateral direction of said conductive sections to relax a stress applied to said bumps.

2. The semiconductor device according to claim 1, wherein said insulating film covers said semiconductor chip other than the surfaces of said conductive sections without including a printed circuit board.

3. The semiconductor device according to claim 1, wherein said stress buffering layer has an elastic modulus in a range of 0.01 to 8 Gpa.

4. The semiconductor device according to claim 1, wherein said stress buffering layer is formed of material comprising at least one selected from a group consisting of epoxy-based resin, silicon-based resin, polyimide-based resin, polyolefin-based resin, cyanate-ester-based resin, phenol-based resin, naphthalene-based resin, and fluorine-based resin.

5. The semiconductor device according to claim 1, wherein said stress buffering layer includes a plurality of buffering layers, each of which is formed of material comprising at least one selected from a group consisting of epoxy-based resin, silicon-based resin, polyimide-based resin, polyolefin-based resin, cyanate-ester-based resin, phenol-based resin, naphthalene-based resin, and fluorine-based resin.

6. The semiconductor device according to claim 5, wherein each of said conductive sections includes a plurality of portions respectively corresponding to said plurality of buffering layers.

7. The semiconductor device according to claim 1, wherein said conductive section is connected to said pad via a wiring pattern provided on said semiconductor chip via a first insulting film of said insulating film.

8. The semiconductor device according to claim 7, wherein said wiring pattern is formed of copper (Cu).

9. The semiconductor device according to claim 7, wherein said wiring pattern extends to adjust a pitch between said conductive bump and another conductive bump.

10. The semiconductor device according to claim 7, wherein said first insulating film includes:
a passivation film covering said semiconductor chip other than said pads; and
a second insulating film formed on said passivation film.

11. The semiconductor device according to claim 10, wherein said second insulating film has a pyrolysis temperature of 200° C. or more.

12. The semiconductor device according to claim 10, wherein said second insulating film is formed of a photosensitive material.

13. A method of manufacturing a semiconductor device, comprising:
(a) providing a semiconductor substrate formed on which pads are formed and on which a first insulating film are formed to have openings, said pads being exposed by said openings;
(b) forming wiring patterns to extend on said first insulating film and to be respectively connected to said pads;
(c) forming a stress buffering layer on said wiring patterns and said first insulating film, said buffering layer including conductive sections respectively connected to said wiring patterns and a buffering and insulating layer formed to surround said conductive sections on lateral sides thereof; and
(d) forming conductive bumps on surfaces of said conductive sections.

14. The method according to claim 13, further comprising:
(e) separating said semiconductor substrate into semiconductor chips.

15. The method according to claim 13, wherein said (a) providing includes:
forming said pads;
forming a passivation film on said semiconductor substrate to have openings in said pads; and
forming a second insulating film formed on said passivation film.

16. The method according to claim 15, wherein said second insulating film is formed of material having a pyrolysis temperature of 200° C. or more.

17. The method according to claim 15, wherein said second insulating film is formed of a photosensitive material.

18. The method according to claim 13, wherein said (b) forming includes:
carrying out electrolysis plating to produce a conductive layer; and
patterning said conductive layer to produce said wiring patterns.

19. The method according to claim 13, wherein said (c) forming includes:
connecting said conductive sections to said wiring patterns;
forming said buffering and insulating layer to cover said first insulating film and said wiring patterns; and
polishing said buffering and insulating layer and said conductive sections to expose said surfaces of said conductive sections.

20. The method according to claim 19, wherein said buffering and insulating layer has an elastic modulus in a range of 0.01 to 8 Gpa.

21. The method according to claim 19, wherein said buffering and insulating layer is formed of material comprising at least one selected from a group consisting of epoxy-based resin, silicon-based resin, polyimide-based resin, polyolefin-based resin, cyanate-ester-based resin, phenol-based resin, naphthalene-based resin, and fluorine-based resin.

22. The method according to claim 13, wherein said buffering and insulating film includes first and second buffering and insulating films, and each of said conductive sections includes first and second conductive sections, and
said (c) forming includes:
connecting said first conductive sections to said wiring patterns;
forming said first buffering and insulating layer to cover said first insulating film and said wiring patterns;
polishing said first buffering and insulating layer and said first conductive sections to expose said surfaces of said first conductive sections;
connecting said second conductive sections to said first conductive sections;
forming said second buffering and insulating layer to cover said first buffering and insulating layer and said second conductive sections; and
polishing said second buffering and insulating layer and said second conductive sections to expose said surfaces of said second conductive sections.

23. The method according to claim 22, wherein each of said first and second buffering and insulating layers has an elastic modulus in a range of 0.01 to 8 Gpa.

24. The method according to claim 22, wherein each of said first and second buffering and insulating layers is formed of material comprising at least one selected from a group consisting of epoxy-based resin, silicon-based resin, polyimide-based resin, polyolefin-based resin, cyanate-ester-based resin, phenol-based resin, naphthalene-based resin, and fluorine-based resin.
